(19) United States
(12) Patent Application Publication
(10) Pub. No.: US 2018/0158903 A1
(43) Pub. Date: Jun. 7, 2018

(54) METHOD OF FABRICATING STI TRENCH AND STI STRUCTURE

(71) Applicant: UNITED MICROELECTRONICS CORP., Hsin-Chu City (TW)

(72) Inventor: Tsung-Chieh Yang, Tainan City (TW)

(21) Appl. No.: 15/369,895

(22) Filed: Dec. 6, 2016

(51) Int. Cl. H01L 29/06; H01L 21/306; H01L 21/762; H01L 21/308

(52) U.S. Cl. CPC H01L 29/0649; H01L 21/3081; H01L 21/76232; H01L 21/30608

(57) ABSTRACT

A method of fabricating an STI trench has a sidewall with two different slopes. The fabricating steps include providing a substrate with a patterned mask thereon. Then, a first trench is formed in the substrate by taking the patterned mask as a mask, wherein the first trench includes a first sidewall and a bottom. Later, a treatment process is performed to form a dielectric layer contacting the first sidewall and the bottom. Finally, after performing the treatment process, the dielectric layer on the bottom of the first trench is removed and the bottom of the first trench and the substrate are also removed to form a second trench by taking the patterned mask as a mask. The first trench and the second trench form the STI trench.

### BACKGROUND OF THE INVENTION

### 1. Field of the Invention

The present invention relates to a method of fabricating a shallow trench isolation (STI) trench, and more particularly to an STI trench having a sidewall with two different slopes.

### 2. Description of the Prior Art

Increased packing density makes isolation techniques that electrically isolate mutually adjacent devices very important. A shallow trench isolation (STI) is a device isolation technique. In an STI, a trench that defines an active region formed in a semiconductor substrate. Then, the inside of the trench is filled with an insulating material.

STIs are widely adopted in an integrated circuit (IC) to provide electrical isolation between adjacent semiconductor devices formed in a substrate. For example, STIs are typically formed between NMOS or PMOS transistors to suppress leakage current between neighboring devices.

However, along with the trend of integrating, more and more circuit functions being performed in a single IC continues, and the structure of existing STIs is gradually becoming one of the major bottlenecks for the further device feature size scaling in advanced technology.

### SUMMARY OF THE INVENTION

It is a primary objective of the present invention to provide a method of fabricating an STI structure without seams formed in the STI filling.

An aspect of the disclosure provides a method of fabricating an STI trench, and includes providing a substrate with a patterned mask thereon. Then, a first trench is formed in the substrate by taking the patterned mask as a mask, wherein the first trench includes a first sidewall and a bottom. Later, a treatment process is performed to forma dielectric layer contacting the first sidewall and the bottom. Finally, after performing the treatment process, the dielectric layer on the bottom of the first trench is removed and the bottom of the first trench and the substrate are removed to form a second trench by taking the patterned mask as a mask.

Another aspect of the disclosure provides an STI structure, and includes a substrate and an STI trench disposed in the substrate. The STI trench includes a first trench including a first sidewall. A second trench connects to the first trench. The second trench includes a second sidewall. A slope of the first sidewall is smaller than a slope of the second sidewall. An STI filling is disposed in the first trench and the second trench. A gap is disposed within the STI filling and in the second trench.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 6 depict a method of fabricating an STI trench according to a preferred embodiment of the present invention.

FIG. 7 depicts an STI structure according to a preferred embodiment of the present invention.

FIG. 8 depicts an STI structure according to another preferred embodiment of the present invention.

### DETAILED DESCRIPTION

FIG. 1 to FIG. 6 depict a method of fabricating an STI trench according to a preferred embodiment of the present invention.

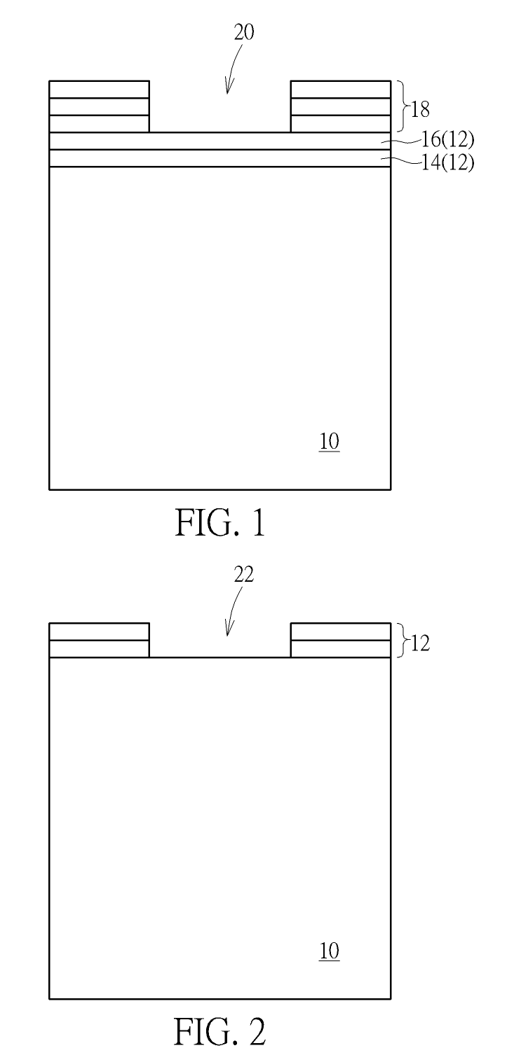

As shown in FIG. 1, a substrate 10 is provided. The substrate 10 may be a bulk silicon substrate, a germanium substrate, a gallium arsenide substrate, a silicon germanium substrate, an indium phosphide substrate, a gallium nitride substrate, a silicon carbide substrate, or a silicon on insulator (SOI) substrate. In this embodiment, the substrate 10 is preferably a bulk silicon substrate. The substrate 10 is covered by a first mask 12. The first mask 12 may include a pad oxide layer 14 and a pad nitride layer 16. A second mask 18 is covered on the first mask 12. The second mask 18 may include an advanced patterned film (APF), an anti-reflective coating (DARC) and a bottom anti-reflective coating (BARC) disposed from bottom to top. Then, the second mask 18 is patterned by a lithographic process by using a patterned photoresist (not shown) as a mask to form an opening 20. As shown in FIG. 2, the first mask 12 is patterned to transfer the opening 20 in the second mask 18 to the first mask 12. Therefore, an opening 22 corresponding to the opening 20 is formed in the first mask 12. Now, part of the substrate 10 is exposed through the opening 22. After that, the second mask 18 and the patterned photoresist are removed. During the removal of the second mask 18 and the patterned photoresist, a silicon oxide layer (not shown) may be formed on the substrate 10 as a byproduct. Later, the silicon oxide layer can be removed by CF₄.

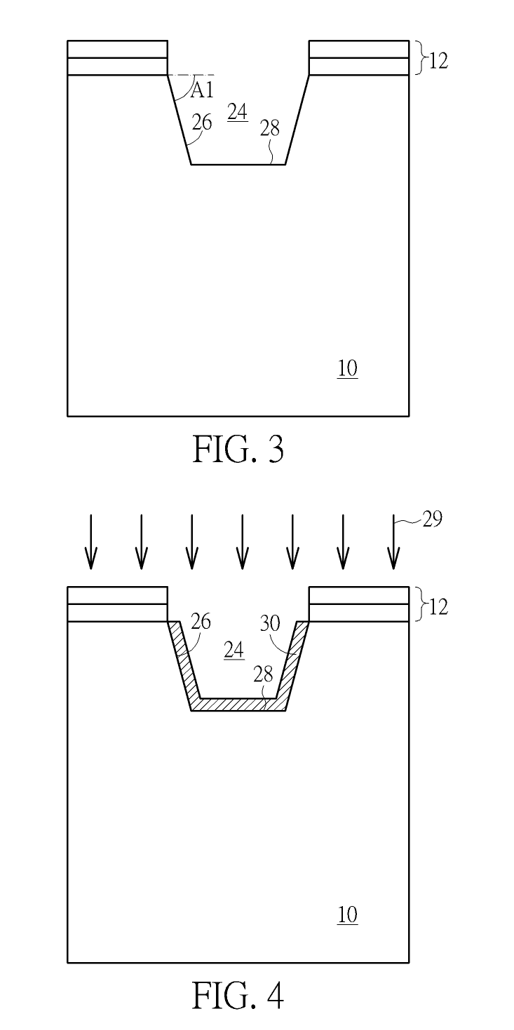

As shown in FIG. 3, a first etching process is performed to etch substrate 10 to form a first trench 24 by taking the first mask 12 as a mask. The first trench 24 includes a first sidewall 26 and a first bottom 28. The first sidewall 26 is the inner sidewall of the first trench 24. The first etching process may be anisotropic ion etching based on plasma. A preferred etchant of the first etching process is bromine source such as HBr, Br₂, CF₃Br or other similar compounds can be used as a silicon etchant. The first sidewall 26 of the first trench 24 is sloped at an angle A1 between 87 and 89 degrees. The angle A1 is defined between the first sidewall 26 and a first extension line of the top surface of the substrate 10. The first extension line is shown by a dash-dotted line.

As shown in FIG. 4, a treatment process 29 performed to form a dielectric layer 30 contacting the first sidewall 26 and the first bottom 28 of the first trench 24. The dielectric layer 30 may include silicon oxide, silicon nitride, silicon oxynitride, silicon carbide, silicon carbon nitride or silicon oxycarbonitride. The dielectric layer 30 is preferably silicon oxide. The treatment process 29 is performed by using nitrogen-containing gas or oxygen-containing gas to flush the first sidewall 26 and the first bottom 28. The nitrogen-containing gas or the oxygen-containing gas will react with the substrate 10, and form the dielectric layer 30 on the first sidewall 26 and the first bottom 28. The nitrogen-containing gas includes N₂ or NH₃. The oxygen-containing gas includes O₂ or O₃. In one embodiment, the treatment process 29 can be an O₂ flush process performed at pressure between 8.5 and 11.5 millitorr, power between 510 and 690 watts, operating time between 25 and 35 seconds, flowing rate of O₂ between 170 and 230 sccm and a temperature of the substrate 10 between 51 and 69 degrees Celsius. The dielectric layer 30 formed by the O₂ flush process is silicon oxide. The dielectric layer 30 has a uniform thickness.

As shown in FIG. 5, the dielectric layer 30 on the first bottom 28 is removed. Etching gas such as a fluorine-containing gas, a chlorine-containing gas, or an oxygen-containing gas may be selected according to the material of the dielectric layer 30. When the dielectric layer 30 is silicon oxide, the dielectric layer 30 may be removed by CF₄. Later, a second etching process is performed to etch the first bottom 28 of the first trench 24 and the substrate 10 to form a second trench 32 by taking the first mask 12 as a mask. The second trench 32 connects to the first trench 24. More specifically speaking, the second trench 32 is formed by etching the substrate 10 below the first trench 24 while the first sidewall 26 is protected by the dielectric layer 30. The second etching process may be an anisotropic ion etching based on plasma. A preferred etchant of the second etching process is bromine source such as HBr, Br₂, CF₃Br or other similar compounds can be used as a silicon etchant. In this embodiment, the second etching process primarily etches the substrate 10 in a vertical direction. Therefore, the first sidewall 26 of the first trench 24 protected by the dielectric layer 30 will maintain its slope during the second etching process. The second trench 32 includes a second sidewall 34 and a second bottom 36. The second sidewall 34 is the inner sidewall of the second trench 32. A slope of the first sidewall 26 is smaller than a slope of the second sidewall 34. In detail, the second sidewall 34 is sloped at an angle A2 between 89 and 90 degrees. The angle A2 is defined between the second sidewall 34 and a second extension line parallel to the first extension line. The second extension line is shown by a dashed line.

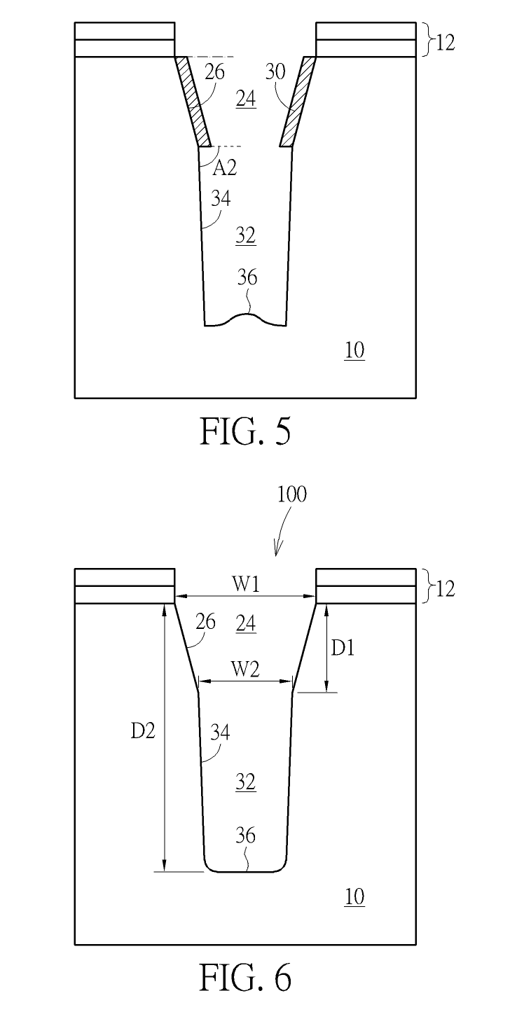

As shown in FIG. 6, the second bottom 36 is smoothed and corners of the second bottom 36 are rounded. The bottom rounding process may be performed by using gas mixture of HBr, He, and O₂. Now, an STI trench 100 of the present invention is completed. Later, the dielectric layer 30 is removed completely. The STI trench 100 is formed by the first trench 24 and the second trench 32. The first trench 24 has a first depth D1, the STI trench 100 has a second depth D2, and the first depth D1 is not less than ⅓ of the second depth D2. According to a preferred embodiment of the present invention, a width W1 of the STI trench 100 is between 50 and 60 nm. The depth D1 of the STI trench 100 is between 210 and 270 nm.

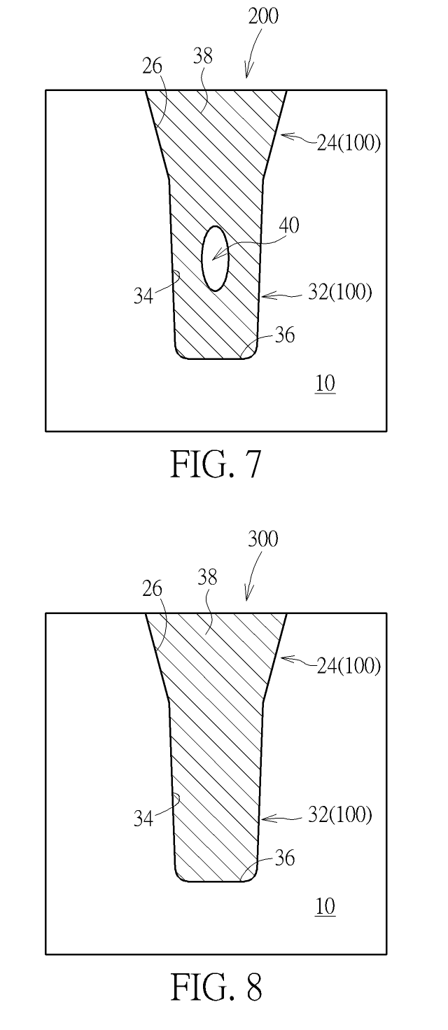

FIG. 7 depicts an STI structure according to a preferred embodiment of the present invention. FIG. 7 is continuous from FIG. 6, wherein like reference numerals are used to refer to like elements throughout. As shown in FIG. 7, an STI filling 38 fills in the STI trench 100. The STI filling 38 may be silicon oxide. A gap 40 is disposed in the STI filling 38. The gap 40 is only in the second trench 32 and does not extend in the first trench 24. After that, the first mask 12 is removed entirely. Now, a STI structure 200 of the present invention is completed. The STI structure 200 includes a substrate 10, and an STI trench 100 disposed in the substrate 10. The STI trench 100 includes a first trench 24 and a second trench 32 connecting to the first trench 24. The first trench 24 includes a first sidewall 26. The second trench 32 includes a second sidewall 34. A slope of the first sidewall 26 is smaller than a slope of the second sidewall 34. A STI filling 38 is disposed in the first trench 24 and the second trench 32. A gap 40 is disposed within the STI filling 38 and in the second trench 34. The first sidewall 26 of the first trench 24 is sloped at an angle A1 between 87 and 89 degrees. The second sidewall 34 is sloped at an angle A2 between 89 and 90 degrees. Please refer to FIG. 3 for the position of the angle A1, and refer to FIG. 5 for the position of the angle A2. The angle A1 is defined between the first sidewall 26 and a first extension line of the top surface of the substrate 10. The first extension line is shown by a dash-dotted line. The angle A2 is defined between the second sidewall 34 and a second extension line parallel to the first extension line. The second extension line is shown by a dashed line. Furthermore, as shown in FIG. 6, a width of an opening of the first trench 24 equals to the width W1 of the STI trench 100. An opening of the second trench 32 has a width W2. The width W1 is greater than the width W2.

FIG. 8 depicts an STI structure according to another preferred embodiment of the present invention. FIG. 8 is continuous from FIG. 6, wherein like reference numerals are used to refer to like elements throughout. As shown in FIG. 8, the STI structure 300 has an STI filling 38 that fills up the STI trench 100. The difference between FIG. 7 and FIG. 8 is that there is a gap 40 disposed in the STI filling 38 in FIG. 7, while there is no gap disposed in the STI filling 38 in FIG. 8. The STI filling 38 can be formed by conventional deposition process such as chemical vapor deposition (CVD). By controlling the gap filling capability, the gap 40 can be selectively formed or not formed in the STI filling 38. For example, if a flowable chemical vapor deposition (FCVD) technique is used, the gap 40 is not formed in the STI filling 38. If a semi-atmosphere chemical vapor deposition (SACVD) technique is used, the gap 40 is formed in the STI filling 38.

The method of fabricating the STI trench of present invention can form a STI trench having a sidewall with two different slopes. The slope of the upper sidewall is smaller than the slope of the lower sidewall. In this way, the STI trench can be formed to a desired depth. Furthermore, if there is an air gap in the STI filling, the air gap will be formed at lower portion of the STI trench. Therefore, the air gap will not become a seam after removing the first mask.

Those skilled in the art will readily observe that numerous modifications and alterations of the device and method may be made while retaining the teachings of the invention. Accordingly, the above disclosure should be construed as limited only by the metes and bounds of the appended claims.

1. A method of fabricating an STI trench, comprising:
providing a substrate with a patterned mask thereon;
forming a first trench in the substrate by taking the patterned mask as a mask, wherein the first trench comprises a first sidewall and a bottom;
performing a treatment process to form a dielectric layer contacting the first sidewall and the bottom;
after performing the treatment process, removing the dielectric layer on the bottom of the first trench and removing the bottom of the first trench and the substrate to form a second trench by taking the patterned mask as a mask;
after forming the second trench, removing the dielectric layer entirely; and
forming an STI filling directly contacting the first trench and the second trench.

2. The method of fabricating an STI trench of claim 1, wherein the dielectric layer comprises silicon oxide, silicon nitride, silicon oxynitride, silicon carbide, silicon carbon nitride or silicon oxycarbonitride.

3. The method of fabricating an STI trench of claim 1, wherein the treatment process is performed by using an oxygen-containing gas.

4. The method of fabricating an STI trench of claim 1, wherein the treatment process is performed by using a nitrogen-containing gas.

5. The method of fabricating an STI trench of claim 1, wherein the first trench connects to the second trench.

6. The method of fabricating an STI trench of claim 1, wherein the first sidewall is sloped at an angle between 87 and 89 degrees.

7. The method of fabricating an STI trench of claim 1, wherein the second trench comprises a second sidewall, and the second sidewall is sloped at an angle between 89 and 90 degrees.

8. The method of fabricating an STI trench of claim 1, wherein a slope of the first sidewall is smaller than a slope of the second sidewall.

9. The method of fabricating an STI trench of claim 1, wherein the first trench and the second trench form the STI trench.

10. The method of fabricating an STI trench of claim 9, wherein the first trench has a first depth, the STI trench has a second depth, and the first depth is not less than ⅓ of the second depth.

11. The method of fabricating an STI trench of claim 6, wherein a width of the STI trench is between 50 and 60 nm.

12. The method of fabricating an STI trench of claim 1, wherein a depth of the STI trench is between 210 and 270 nm.

13. The method of fabricating an STI trench of claim 1, wherein the first trench is formed by etching the substrate with HBr.

14. The method of fabricating an STI trench of claim 1, wherein the second trench is formed by removing the dielectric layer on the bottom by CF₄ followed by etching the substrate with HBr.

15. The method of fabricating an STI trench of claim 1, further comprising a bottom rounding process after forming the second trench, wherein the bottom rounding process is performed by using HBr, He, and O₂ to smooth a bottom of the second trench.

16. An STI structure, comprising:
a substrate;
an STI trench disposed in the substrate, wherein the STI trench comprises:
a first trench comprising a first sidewall;
a second trench connecting to the first trench, and comprising a second sidewall, wherein a slope of the first sidewall is smaller than a slope of the second sidewall;
an STI filling disposed in the first trench and the second trench; and
a gap disposed within the STI filling and in the second trench.

17. The STI structure of claim 16, wherein the first sidewall is sloped at an angle between 87 and 89 degrees.

18. The STI structure of claim 16, wherein the second sidewall is sloped at an angle between 89 and 90 degrees.

19. The STI structure of claim 16, wherein gap does not extend to the first trench.

20. The STI structure of claim 16, wherein the first trench has a first depth, the STI trench has a second depth, and the first depth is not less than ⅓ of the second depth.
